(19) United States
(12) Patent Application Publication
(10) Pub. No.: US 2026/0353876 A1
(43) Pub. Date: Nov. 5, 2026

(54) VENTED LUMIPHORIC MATERIAL STRUCTURES IN LIGHT-EMITTING DIODE PACKAGES

(71) Applicant: CreeLED, Inc., Durham, NC (US)

(72) Inventors: Robert Wilcox, Rolesville, NC (US); Michael Check, Holly Springs, NC (US); David Suich, Durham, NC (US); Joseph G. Sokol, Durham, NC (US); Andre Pertuit, Raleigh, NC (US); Colin Blakely, Raleigh, NC (US)

(21) Appl. No.: 19/196,860

(22) Filed: May 2, 2025

(51) Int. Cl. H10H 20/851; H10H 20/85; H10H 20/853; H10H 20/856

(52) U.S. Cl. CPC H10H 20/8514; H10H 20/8506; H10H 20/853; H10H 20/856

(57) ABSTRACT

Light-emitting diode (LED) devices and more particularly vented lumiphoric material structures in LED packages are disclosed. Lumiphoric material structures include pre-formed structures that are shaped and subsequently attached to corresponding LED packages. One or more pre-formed apertures are provided that form venting pathways when attached. Lumiphoric material structures form cavities over underlying LED chips and venting pathways provide thermal dissipation for the lumiphoric material structure. LED packages may further include light-altering materials positioned about LED chip perimeters on support structures. The light-altering materials may form light-reflective and/or light-blocking structures positioned to reduce amounts of light from the LED chip that escapes apertures of the lumiphoric material structures.

### FIELD OF THE DISCLOSURE

The present disclosure relates to light-emitting diode (LED) devices, and more particularly to vented lumiphoric material structures in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. LED packages may also include lumiphoric materials provided for wavelength conversion. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to vented lumiphoric material structures in LED packages. Lumiphoric material structures include pre-formed structures that are shaped and subsequently attached to corresponding LED packages. One or more pre-formed apertures are provided that form venting pathways when attached. Lumiphoric material structures form cavities over underlying LED chips and venting pathways provide thermal dissipation for the lumiphoric material structure. LED packages may further include light-altering materials positioned about LED chip perimeters on support structures. The light-altering materials may form light-reflective and/or light-blocking structures positioned to reduce amounts of light from the LED chip that escapes apertures of the lumiphoric material structures.

In one aspect, an LED package comprises: a support structure; an LED chip on a first face of the support structure; a lumiphoric material structure on the first face of the support structure such that a cavity is at least partially formed between the lumiphoric material structure and the support structure, the cavity being registered with the LED chip and configured to allow air flow between an interior volume of the cavity and an ambient environment outside the LED package; and a light-altering material on a portion of the first face of the support structure within the cavity, the light-altering material forming a reflective structure about a perimeter of the LED chip. In certain embodiments, the lumiphoric material structure forms at least one aperture arranged to allow the air flow from outside the LED package. In certain embodiments, the at least one aperture is defined by an opening of the lumiphoric material structure that is positioned at the first surface of the support structure. In certain embodiments, a height of the light-altering material is greater than a height of the at least one aperture relative to the first face of the support structure. In certain embodiments, wherein the at least one aperture comprises two apertures on portions of the support structure that correspond with opposing sides of the LED chip. In certain embodiments, the at least one aperture comprises four apertures on portions of the support structure that correspond with all sides of the LED chip. In certain embodiments, the lumiphoric material structure comprises a phosphor-in-glass structure. In certain embodiments, the lumiphoric material structure further forms a planar portion that laterally extends from a curved surface. The LED package may further comprise an adhesive between the planar portion of the lumiphoric material structure and the support structure. In certain embodiments, the light-altering material forms a curved ring on the support structure. In certain embodiments, the light-altering material forms a shape with one or more linear portions on the support structure. The LED package may further comprise a eutectic bond between the lumiphoric material structure and the support structure. In certain embodiments, the lumiphoric material structure forms one of a hemispherical shape, a bullet shape, or a shape with a planar upper surface.

In one aspect, an LED package comprises: a support structure; an LED chip on a first face of the support structure; and a lumiphoric material structure on the first face of the support structure such that a cavity is at least partially formed between the lumiphoric material structure and the support structure, the cavity being registered with the LED chip and configured to allow air flow between an interior volume of the cavity and an ambient environment outside the LED package, the lumiphoric material structure forming a lens over the LED chip and the lumiphoric material structure forming a planar portion laterally extending from a perimeter of the lens, the planar portion being bonded to the support structure. In certain embodiments, the lens forms a curved surface above the LED chip and the planar portion forms a ledge laterally extending from a base of the lumiphoric material structure. The LED package may further comprise an adhesive between the planar portion and the support structure. In certain embodiments, the lumiphoric material structure forms at least one aperture arranged to allow the air flow from outside the LED package. In certain embodiments, the at least one aperture is defined by an opening of the lumiphoric material structure that is positioned at the first surface of the support structure. In certain embodiments, the at least one aperture comprises two apertures on portions of the support structure that correspond with opposing sides of the LED chip. The LED package may further comprise a eutectic bond between the planar portion and the support structure. In certain embodiments, the eutectic bond is formed by a first metal layer on the planar portion and a second metal layer on the support structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package with venting according to aspects of the present disclosure.

FIG. 1B is a cross-sectional view of the LED package of FIG. 1A taken along the sectional line 1B-1B of FIG. 1A.

FIG. 1C is a cross-sectional view of the LED package of FIG. 1A taken along the sectional line 1C-1C of FIG. 1A that includes the apertures.

FIG. 1D is a side view of the LED package of FIG. 1A from a perspective that includes at least one aperture.

FIG. 2 is a top view of an LED package that is similar to the LED package of FIGS. 1A to 1D for embodiments with additional apertures.

FIG. 3 is a top view of an LED package that is similar to the LED package of FIGS. 1A to 1D for embodiments where the light-altering material forms a shape with one or more linear portions.

FIG. 4A is a top view of an LED package that is similar to the LED package of FIGS. 1A to 1D for embodiments where the light-altering material of FIG. 1A is omitted.

FIG. 4B is a cross-sectional view of the LED package of FIG. 4A taken along the sectional line 4B-4B of FIG. 4A.

FIG. 4C is a cross-sectional view of the LED package of FIG. 4A taken along the sectional line 4C-4C of FIG. 4C.

FIG. 4D is a side view of the LED package of FIG. 4A from a perspective that includes at least one aperture.

FIG. 5 is a cross-sectional view of an LED package that is similar to the LED package of FIGS. 1A to 1D for embodiments where the lumiphoric material structure is bonded to the support structure by way of a metal-to-metal bond.

FIG. 6A is a cross-sectional view of an LED package that is similar to the LED package of FIGS. 1A to 1D for embodiments with an alternative shape for the lumiphoric material structure and from a perspective that illustrates a bonding interface between the lumiphoric material structure and the support element.

FIG. 6B is a cross-sectional view of the LED package of FIG. 6A from a perspective that illustrates the one or more apertures.

FIG. 7A is a cross-sectional view of an LED package that is similar to the LED package of FIGS. 1A to 1D for embodiments with another alternative shape for the lumiphoric material structure and from a perspective that illustrates a bonding interface between the lumiphoric material structure and the support element.

FIG. 7B is a cross-sectional view of the LED package of FIG. 7A from a perspective that illustrates the one or more apertures.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to vented lumiphoric material structures in LED packages. Lumiphoric material structures include pre-formed structures that are shaped and subsequently attached to corresponding LED packages. One or more pre-formed apertures are provided that form venting pathways when attached. Lumiphoric material structures form cavities over underlying LED chips and venting pathways provide thermal dissipation for the lumiphoric material structure. LED packages may further include light-altering materials positioned about LED chip perimeters on support structures. The light-altering materials may form light-reflective and/or light-blocking structures positioned to reduce amounts of light from the LED chip that escapes apertures of the lumiphoric material structures.

Before delving into aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

The active LED structure for a given LED chip may be configured to generate certain wavelengths of light depending on the composition of the active layer. In certain embodiments, the active LED structure is configured to generate blue light with a peak wavelength range of approximately 430 nanometers (nm) to 480 nm. In other embodiments, the active LED structure generates green light with a peak wavelength range of 500 nm to 570 nm. In other embodiments, the active LED structure generates red light with a peak wavelength range of 600 nm to 700 nm. In certain embodiments, the active LED structure may be configured to generate light that is outside the visible spectrum, including one or more portions of the ultraviolet (UV) spectrum, or one or more portions of the near infrared spectrum, and/or the infrared spectrum (e.g., 700 nm to 1000 nm). In other applications, UV LEDs may also be provided with one or more lumiphoric materials to provide LED packages with aggregated emissions having a broad spectrum and improved color quality for visible light applications. In various applications, LED packages according to the present disclosure may include arrays of LED chips. In certain embodiments, an LED array within an LED package may include all LED chips of a same emission color. In other embodiments, multiple strings of LED chips having different emission colors may be arranged together to form an LED array.

In certain embodiments, aspects of the present disclosure are applicable to LED packages with a recipient lumiphoric material that converts at least a portion of light generated from one or more LED chips to a different wavelength. For example, an LED chip may be positioned with respect to one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED chip may re-emit light having a different peak wavelength than the LED chip. An LED chip or an LED chip array and one or more lumiphoric materials may be selected such that their combined output results in light with one or more desired characteristics such as color, color point, intensity, etc. In certain embodiments, aggregate emissions of one or more LED chips, in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In certain embodiments, the combination of the LED chip and the one or more lumiphors (e.g., phosphors) is configured to emit a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, and the like. One or more lumiphoric materials may be provided on one or more portions of an LED chip in various configurations. For example, lumiphoric materials may be provided in an encapsulant material configured to cover one or more LED chips, as part of a cover structure with a coating on one or more optical or support elements (e.g., by powder coating, inkjet printing, or the like), and/or being incorporated within a cover structure, such as pre-formed phosphor-in-glass or phosphor-in-silicone structures, ceramic phosphor plates, and/or single crystal phosphors. In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip, and a wire bond is typically used for top-side electrical connections. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or element, such as a lead frame structure or a submount.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. For chip-on-board LED packages, light-altering materials may form a dam about a perimeter of an array of LED chips, and in certain embodiments, an encapsulant material may be formed to cover the LED chips and be retained by the dam.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Lumiphoric materials generate heat during wavelength conversion. In conventional LED packages, lumiphoric materials are formed directly on or in close proximity to LED chips and/or underlying submount structures. This arrangement provides a thermal dissipation pathways from the lumiphoric material to the submount structure. In certain arrangements, having a lumiphoric material layer positioned on the LED chip can create some color-over-angle variances. For example, light traveling in a perpendicular direction from a top surface of the LED chip may pass through a lumiphoric material layer with a shorter path length compared with wider angle light traveling through the lumiphoric material layer. Such different path lengths may provide different amounts of light that are subject to wavelength conversion. Remote lumiphoric materials are sometimes arranged in LED packages to provide improved uniformity of light exiting the LED package. When placed remotely, or in a spaced relationship to the LED chip, pathways of photons from the LED chip that pass through the lumiphoric material may do so with more uniform distances, thereby providing wavelength conversion with improved color-over-angle uniformity. However, remote arrangements for lumiphoric materials may thermally decouple lumiphoric materials from underlying submount structures. In such arrangements, lumiphoric materials could overheat and lead to charring, particularly for lumiphoric materials in a structure that includes silicone. Additionally, remote lumiphoric structures may detach or pop off of an underlying submount structure during operation due to thermal expansion.

According to aspects of the present disclosure, vented lumiphoric material structures are provided in LED packages that promote air flow between an interior volume and an ambient environment outside the LED package. Exemplary venting structures include apertures. With such venting, lumiphoric material structures that are remote from LED chips may exhibit suitable heat dissipation while providing improved uniformity in color-over-angle emissions. In certain embodiments, vented lumiphoric material structures may promote various cooling modes. For example, pre-convection cooling modes for radiant heating may be exhibited where hot layers of gas along surfaces of the lumiphoric material structure are permitted to escape. In the absence of venting, such hot layers of gas could accelerate heating of the lumiphoric material structure.

According to aspects of the present disclosure, lumiphoric material structures include pre-formed structures that are shaped and subsequently attached to corresponding LED packages. One or more pre-formed apertures are provided that form venting pathways when attached. In certain embodiments, lumiphoric material structures may include lumiphoric material particles embedded in a host material, such as a phosphor-in-glass or a sintered ceramic phosphor structure. In other embodiments, lumiphoric material structures may include shaped single crystal phosphor structures. The pre-formed nature allows various lens shapes to be provided that form a cavity over the LED chip when mounted in an LED package. Exemplary lens shapes include various curved shapes, such as a dome, a hemisphere, an oval, or bullet, among others. Additional lens shapes include those with one or more planar surfaces, such as a lens having a curved top surface with planar side surfaces or a square shaped lens. Exemplary LED packages may further include light-altering materials positioned about LED chip perimeters on support structures. The light-altering materials may form light-reflective and/or light-blocking structures positioned to reduce amounts of light from the LED chip that escapes apertures of the lumiphoric material structure.

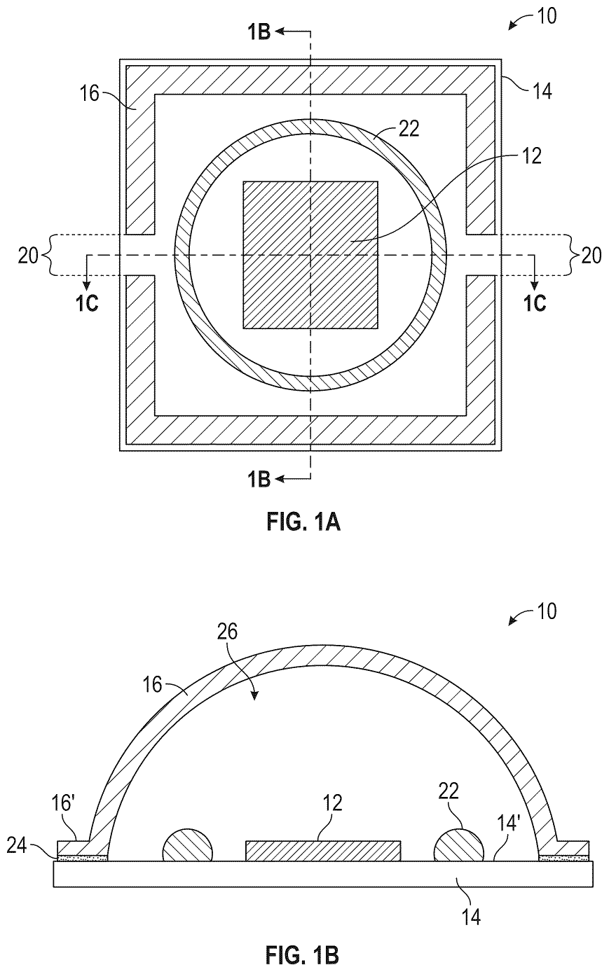

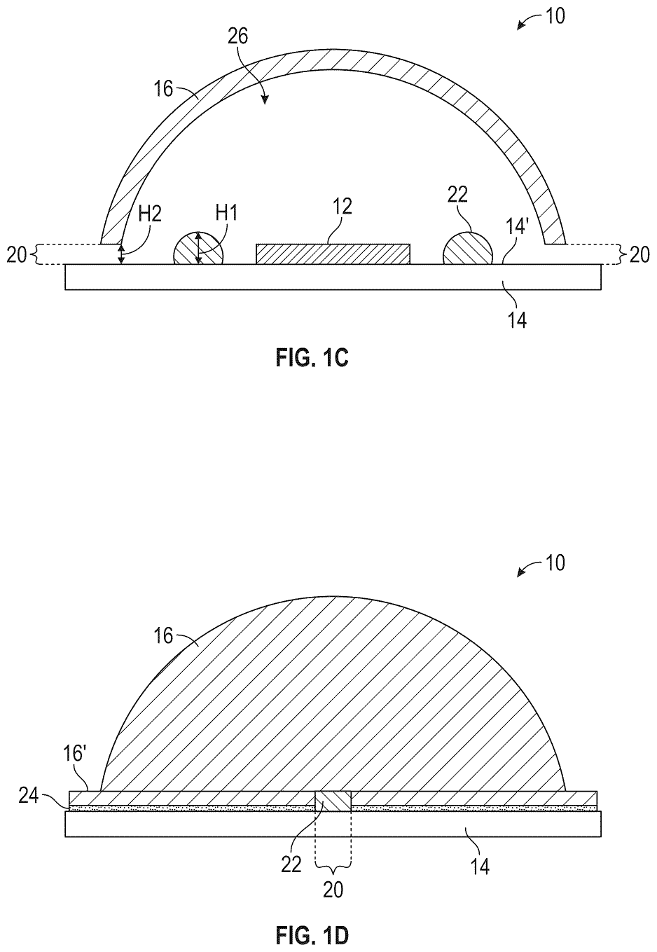

FIG. 1A is a top view of an LED package 10 with venting according to aspects of the present disclosure. The LED package 10 includes an LED chip 12 on a support structure 14, such as a submount or a lead frame structure. A lumiphoric material structure 16 is positioned on the support structure 14 about a perimeter of the LED chip 12 and proximate a perimeter of the support structure 14. For illustrative purposes, only the portion of the lumiphoric material structure 16 that is bonded to the support structure 14 is shown in FIG. 1A. Further details of the lumiphoric material structure 16 are illustrated in the views of the LED package 10 provided by FIGS. 1B to 1D. The lumiphoric material structure 16 forms one or more apertures 20 when bonded to the support structure 14. The apertures 20 form openings that permit air flow between an interior volume of the LED package 10 and an ambient environment outside the LED package 10. In the example of FIG. 1A, two apertures 20 are positioned on opposing sides of the LED chip 12 to permit air flow from one side of the LED package 10 to another. In certain embodiments, the LED package 10 may further include a light-altering material 22 on a portion of the support structure 14 that is between the LED chip 12 and where the lumiphoric material structure 16 is bonded. In this regard, the light-altering material 22 may extend on a portion of the support structure 14 that is between the lumiphoric material structure 16 and the apertures 20. The light-altering material 22 may form a reflective structure about a perimeter of the LED chip 12. In certain embodiments, the light-altering material 22 forms a curved ring shape on the support structure 14 for redirecting and/or blocking light from the LED chip 12 that may otherwise escape through the aperture 20.

FIG. 1B is a cross-sectional view of the LED package 10 of FIG. 1A taken along the sectional line 1B-1B of FIG. 1A. As illustrated, the LED chip 12 is mounted on a first face 14', or a top face, of the support structure 14. The light-altering material 22 and the lumiphoric material structure 16 are also positioned on the first face 14'. The lumiphoric material structure 16 may be bonded to the first face 14', or top face, by way of an adhesive 24. The adhesive 24 may include one or more of silicone, epoxy, or metal bonds. In certain embodiments, the lumiphoric material structure 16 includes a planar portion 16′ laterally extending along a perimeter of the lumiphoric material structure 16 that provides a planar surface for bonding by way of the adhesive 24. For example, the lumiphoric material structure 16 may form a curved surface of a lens over the LED chip 12, and the planar portion 16′ may form a lip or ledge portion that laterally extends from a perimeter and/or base of the lens about a perimeter of the curved surface. When the lumiphoric material structure 16 is bonded to the support structure 14, a cavity 26 is formed over the LED chip 12 and the light-altering material 22. The cavity 26 may embody an air cavity that permits air flow by way of the apertures 20 of FIG. 1A.

FIG. 1C is a cross-sectional view of the LED package 10 of FIG. 1A taken along the sectional line 1C-1C of FIG. 1A that includes the apertures 20. As illustrated, the apertures 20 may defined by an opening of the lumiphoric material structure 16 positioned at the first face 14′ of the support structure 14. By way of example, the apertures 20 may be formed by cut-out shapes of the lumiphoric material structure 16 that are not bonded to the support structure 14, thereby permitting air flow between an interior volume of the cavity 26 and an ambient environment outside the LED package 10. In certain embodiments, a height H1 of the light-altering material 22 may be greater than a height H2 of the apertures 20 in a perpendicular direction relative to the first face 14′ of the support structure 14. In this manner, the light-altering material 22 may be positioned to reduce light from the LED chip 12 that may otherwise exit through the apertures 20 without being subject to wavelength conversion, thereby providing further color-over-angle uniformity improvements. As illustrated, apertures 20 may be formed on portions of the support structure 14 that correspond with opposing sides of the LED chip 12 to permit airflow from one side of the LED package 10 to another. The air flow may propagate within the cavity 26 and along the inner surface of the lumiphoric material structure 16.

FIG. 1D is a side view of the LED package 10 of FIG. 1A from a perspective that includes at least one aperture 20. From the side view, the light-altering material 22 is visible through the aperture 20. Since the height of the light-altering material 22 is greater than a height of the aperture 20 from the support structure 14, the light-altering material 22 is positioned to effectively block a line-of-sight to the LED chip 12 of FIG. 1A. As illustrated, the adhesive 24 may extend between the lumiphoric material structure 16 and the support structure 14 up to the aperture 20.

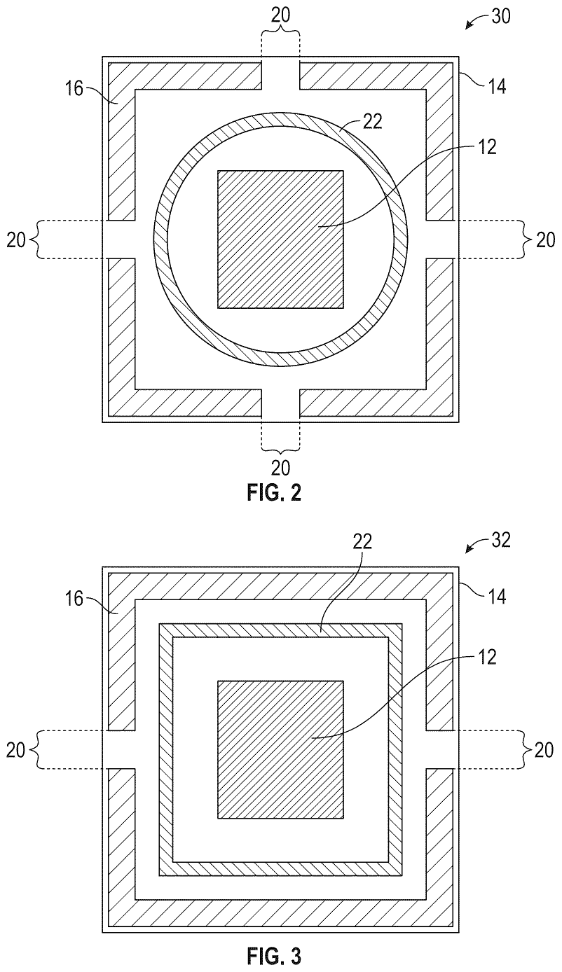

FIG. 2 is a top view of an LED package 30 that is similar to the LED package 10 of FIGS. 1A to 1D for embodiments with additional apertures 20. In the example of FIG. 2, four apertures 20 are positioned on portions of the support structure 14 that correspond with all sides of the LED chip 12. Accordingly, air flow may propagate between all sides of the LED package 30.

FIG. 3 is a top view of an LED package 32 that is similar to the LED package 10 of FIGS. 1A to 1D for embodiments where the light-altering material 22 forms a shape with one or more linear portions. In certain embodiments, the light-altering material 22 may form the shape of a square or a rectangular ring on the support structure 14. Such a shape may generally follow the shape of the support structure 14 and/or a shape of where the lumiphoric material structure 16 is bonded to the support structure 14.

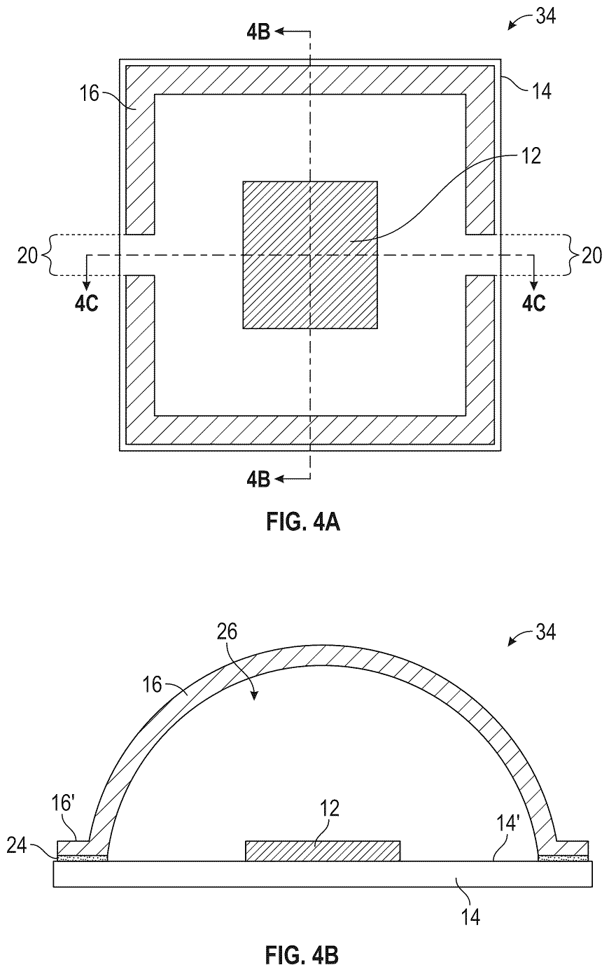

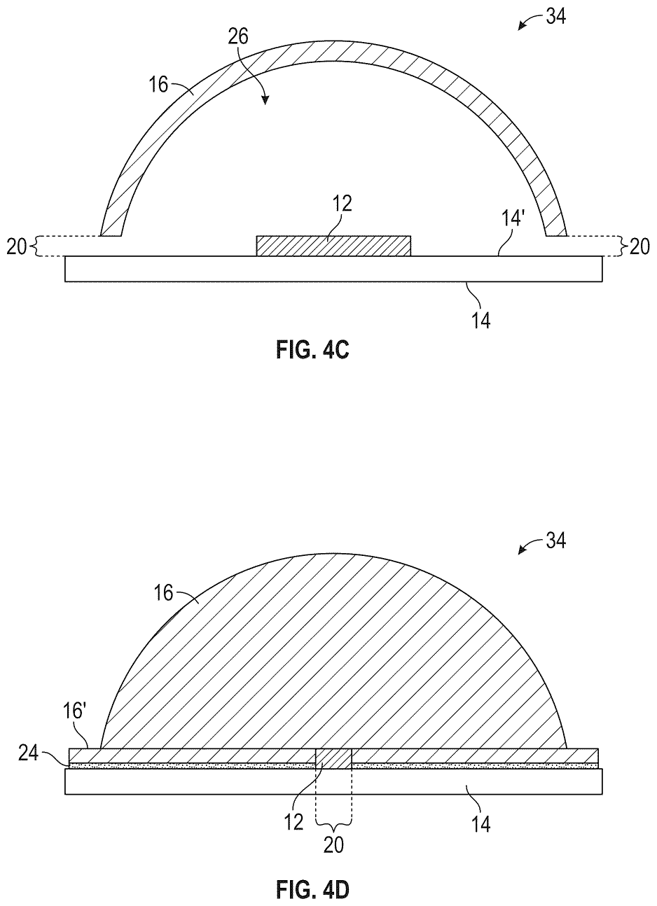

FIG. 4A is a top view of an LED package 34 that is similar to the LED package 10 of FIGS. 1A to 1D for embodiments where the light-altering material 22 of FIG. 1A is omitted. FIG. 4B is a cross-sectional view of the LED package 34 of FIG. 4A taken along the sectional line 4B-4B of FIG. 4A. FIG. 4C is a cross-sectional view of the LED package 34 of FIG. 4A taken along the sectional line 4C-4C of FIG. 4C. FIG. 4D is a side view of the LED package 34 of FIG. 4A from a perspective that includes at least one aperture 20. In certain embodiments, all other elements of the LED package 34 may be the same as described above with respect to the LED package 10 of FIGS. 1A to 1D. By omitting the light-altering material 22 of FIGS. 1A to 1D, a portion of the LED chip 12 may be visible via a line-of-sight through the aperture 20. In certain applications, the amount of light from the LED chip 12 exiting the aperture 20 may be minimal, particularly for embodiments where the height of the aperture 20 is less than a corresponding height of the LED chip 12 from the first face 14′ of the support structure 14. Depending on the desired emission pattern, the light-altering material 22 may be omitted in any of the previous embodiments described above with respect to FIGS. 1A to 3.

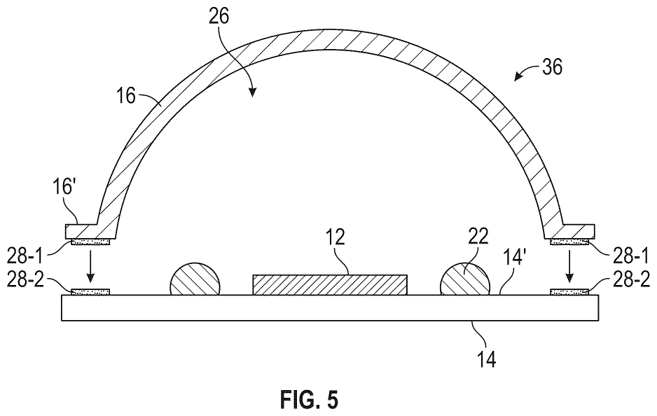

FIG. 5 is a cross-sectional view of an LED package 36 that is similar to the LED package 10 of FIGS. 1A to 1D for embodiments where the lumiphoric material structure 16 is bonded to the support structure 14 by way of a metal-to-metal bond. In certain embodiments, a first metal layer 28-1 may be formed on the lumiphoric material structure 16, and a second metal layer 28-2 may be formed on a corresponding portion of the first face 14′ of the support structure 14. When the lumiphoric material structure 16 is bonded to the support structure 14, the first and second metal layers 28-1, 28-2 may be joined together to form a metal-to-metal bond. In one example, the metal-to-metal bond may comprise a eutectic bond. For example, the first and second metal layers 28-1, 28-2 may be deposited, such as sputtered, on respective portions of the lumiphoric material structure 16 and the support structure 14. The first and second metal layers 28-1, 28-2 may then form a eutectic bond during the bonding process. In certain embodiments, the first metal layer 28-1 forms the first layer on a bottom side of the planar portion 16′. The first and second metal layers 28-1, 28-2 may replace the adhesive 24 of any of the previous embodiments described above with respect to FIGS. 1A to 4D.

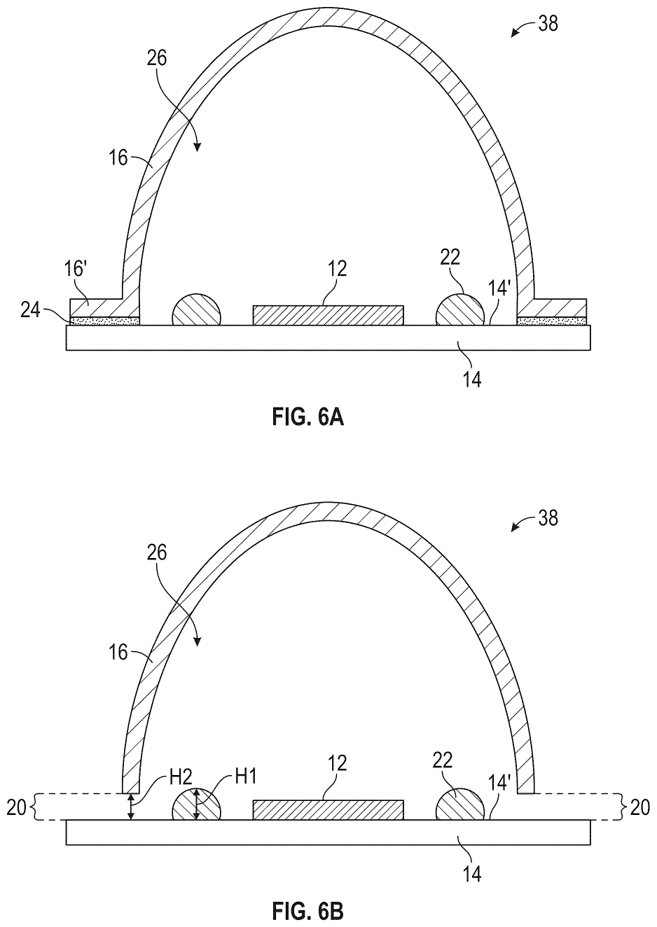

FIG. 6A is a cross-sectional view of an LED package 38 that is similar to the LED package 10 of FIGS. 1A to 1D for embodiments with an alternative shape for the lumiphoric material structure 16. FIG. 6A is a cross-sectional view of the LED package 38 from a perspective similar to FIG. 1B to illustrate a bonding interface between the lumiphoric material structure 16 and the support structure 14 by way of the adhesive 24. FIG. 6B is a cross-sectional view of the LED package 38 from a perspective similar to FIG. 1C to illustrate the one or more apertures 20. The shape of the lumiphoric material structure 16 in FIGS. 6A and 6B is an elongated lens with a curved upper surface, such as a bullet shape. Such a shape may provide a more concentrated beam of focused light as compared to the more hemispherical shape for the LED package 10 of FIGS. 1A to 1D. With reference to FIG. 6A, the elongated shape for the lumiphoric material structure 16 may permit more room on the first face 14′ of the support structure 14 for the planar portion 16′ to extend. Accordingly, the planar portion 16′ may have increased lateral length to permit increased bonding area to the support structure 14 with increased amounts of adhesive 24 therebetween.

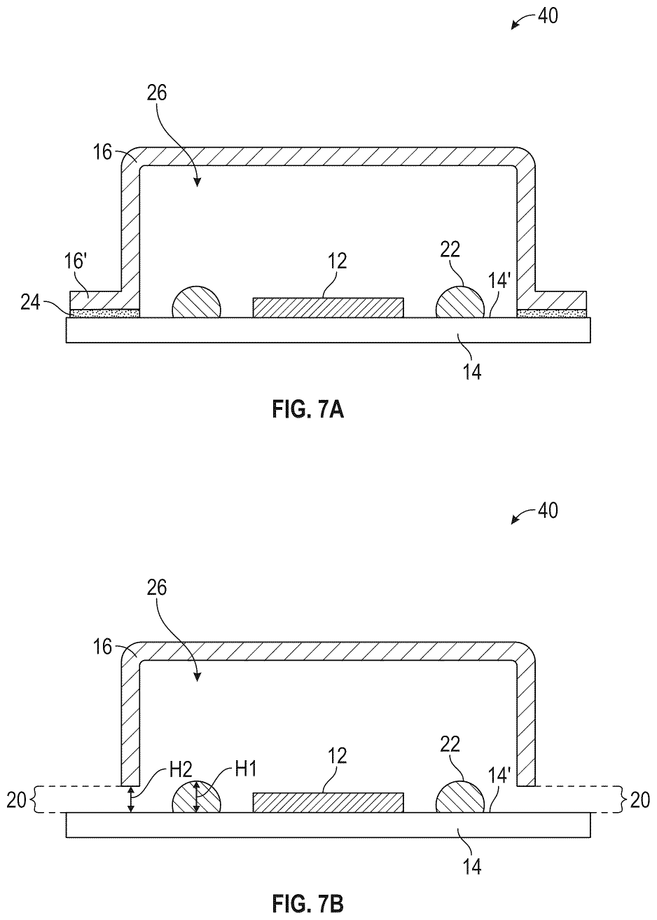

FIG. 7A is a cross-sectional view of an LED package 40 that is similar to the LED package 10 of FIGS. 1A to 1D for embodiments with another alternative shape for the lumiphoric material structure 16. FIG. 7A is a cross-sectional view of the LED package 40 from a perspective similar to FIG. 1B to illustrate a bonding interface between the lumiphoric material structure 16 and the support structure 14 by way of the adhesive 24. FIG. 7B is a cross-sectional view of the LED package 40 from a perspective similar to FIG. 1C to illustrate the one or more apertures 20. The shape of the lumiphoric material structure 16 in FIGS. 7A and 7B forms a generally planar or flat upper surface. In certain embodiments, the shape may form a generally cubic or a rectangular cuboid shape with generally planar sidewalls extending from the upper surface of the lumiphoric material structure 16 towards the support structure 14. The shape of the lumiphoric material structure 16 in FIGS. 7A and 7B may provide increased concentrations of light in a direction perpendicular to the first face 14′ of the support element 14 and may be useful for various applications that require concentrated beams of light. As with the embodiments of FIGS. 6A and 6B, the generally flat shape of FIGS. 7A and 7B may permit the planar portion 16′ to have increased lateral length to permit increased bonding area to the support structure 14 with increased amounts of adhesive 24 therebetween.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support structure;
an LED chip on a first face of the support structure;
a lumiphoric material structure on the first face of the support structure such that a cavity is at least partially formed between the lumiphoric material structure and the support structure, the cavity being registered with the LED chip and configured to allow air flow between an interior volume of the cavity and an ambient environment outside the LED package; and
a light-altering material on a portion of the first face of the support structure within the cavity, the light-altering material forming a reflective structure about a perimeter of the LED chip.

2. The LED package of claim 1, wherein the lumiphoric material structure forms at least one aperture arranged to allow the air flow from outside the LED package.

3. The LED package of claim 2, wherein the at least one aperture is defined by an opening of the lumiphoric material structure that is positioned at the first surface of the support structure.

4. The LED package of claim 3, wherein a height of the light-altering material is greater than a height of the at least one aperture relative to the first face of the support structure.

5. The LED package of claim 2, wherein the at least one aperture comprises two apertures on portions of the support structure that correspond with opposing sides of the LED chip.

6. The LED package of claim 2, wherein the at least one aperture comprises four apertures on portions of the support structure that correspond with all sides of the LED chip.

7. The LED package of claim 1, wherein the lumiphoric material structure comprises a phosphor-in-glass structure.

8. The LED package of claim 7, wherein the lumiphoric material structure further forms a planar portion that laterally extends from a curved surface.

9. The LED package of claim 8, further comprising an adhesive between the planar portion of the lumiphoric material structure and the support structure.

10. The LED package of claim 1, wherein the light-altering material forms a curved ring on the support structure.

11. The LED package of claim 1, wherein the light-altering material forms a shape with one or more linear portions on the support structure.

12. The LED package of claim 1, further comprising a eutectic bond between the lumiphoric material structure and the support structure.

13. The LED package of claim 1, wherein the lumiphoric material structure forms one of a hemispherical shape, a bullet shape, or a shape with a planar upper surface.

14. A light-emitting diode (LED) package comprising:
a support structure;
an LED chip on a first face of the support structure; and
a lumiphoric material structure on the first face of the support structure such that a cavity is at least partially formed between the lumiphoric material structure and the support structure, the cavity being registered with the LED chip and configured to allow air flow between an interior volume of the cavity and an ambient environment outside the LED package, the lumiphoric material structure forming a lens over the LED chip and the lumiphoric material structure forming a planar portion laterally extending from a perimeter of the lens, the planar portion being bonded to the support structure.

15. The LED package of claim 14, wherein the lens forms a curved surface above the LED chip and the planar portion forms a ledge laterally extending from a base of the lumiphoric material structure.

16. The LED package of claim 14, further comprising an adhesive between the planar portion and the support structure.

17. The LED package of claim 14, wherein the lumiphoric material structure forms at least one aperture arranged to allow the air flow from outside the LED package.

18. The LED package of claim 17, wherein the at least one aperture is defined by an opening of the lumiphoric material structure that is positioned at the first surface of the support structure.

19. The LED package of claim 17, wherein the at least one aperture comprises two apertures on portions of the support structure that correspond with opposing sides of the LED chip.

20. The LED package of claim 14, further comprising a eutectic bond between the planar portion and the support structure.

21. The LED package of claim 20, wherein the eutectic bond is formed by a first metal layer on the planar portion and a second metal layer on the support structure.
